(19) United States
(12) Patent Application Publication
(10) Pub. No.: US 2025/0048577 A1
(43) Pub. Date: Feb. 6, 2025

(54) HOUSING FOR A VEHICLE DEVICE AND METHOD FOR PRODUCING A HOUSING

(71) Applicant: HELLA GmbH & Co. KGaA, Lippstadt (DE)

(72) Inventor: Christian HOFFMEIER, Erwitte (DE)

(73) Assignee: HELLA GmbH & Co. KGaA, Lippstadt (DE)

(21) Appl. No.: 18/920,728

(22) Filed: Oct. 18, 2024

Related U.S. Application Data
(63) Continuation of application No. PCT/EP2023/058814, filed on Apr. 4, 2023.

(30) Foreign Application Priority Data
Apr. 22, 2022 (DE) 10 2022 109 731.5

(51) Int. Cl. H05K 5/04; B60R 16/02; H05K 5/00

(52) U.S. Cl. CPC H05K 5/04; B60R 16/02; H05K 5/0004

(57) ABSTRACT

A housing for a vehicle device, the housing at least comprising at least one metal housing lower part having a housing lower part edge having a first joining surface. At least one metal housing upper part has a housing upper part edge having a second joining surface. The housing upper part edge having the second joining surface arranged on the housing lower part edge having the first joining surface so as to form a joint to one another. A seal is arranged in the joint, and the housing upper part edge is integrally bonded to the housing lower part edge at least at one welding portion of the housing via a beam welding process in the joint at least for mechanical stabilization of the housing.

This nonprovisional application is a continuation of International Application No. PCT/EP2023/058814, which was filed on Apr. 4, 2023, and which claims priority to German Patent Application No. 10 2022 109 731.5, which was filed on Apr. 22, 2022, and which are both herein incorporated by reference.

### BACKGROUND OF THE INVENTION

### Field of the Invention

The present invention relates to the field of housings as well as to the field of laser welding and relates to a housing for a vehicle device as well as a method for manufacturing a housing of this type.

### Description of the Background Art

Friction stir welding is a method which may be used to integrally bond two or multiple components. In friction stir welding, the fictional energy is generated by a rotating friction stir tool. The friction stir tool comprises a welding probe and a shoulder. Heat is generated by friction between the shoulder of the friction stir tool and the component, thereby reducing the flow stress in the joining region. The components may thus be easily deformed, and a flow zone forms around the friction stir tool. In the flow zone, the material of the components may be transported around the friction stir tool. The components are mixed locally and integrally bonded by moving the friction stir tool along a joint to be welded. Friction stir welding is suitable for joining aluminum (Al) or its alloys, in particular, for joining die-cast components made from aluminum alloys. Al die-cast components are frequently free of pores in the edge layers, but do have pores in the core layer. However, die-cast components have the advantage that they may be provided with a very functionally rich design, for example having integrated cooling ribs, recesses for connectors, etc., and thus take on complex structures or shapes. In the friction stir welding of aluminum alloys, problems advantageously do not arise, such as the hot cracking problems and pore formation which occur, for example, in fusion welding, in particular laser welding. However, one problem with friction stir welding is that the joining of a geometrically complex joint, which may occur, for example, in a die-cast component, is highly complex or not even possible at all, since the shoulder of the friction stir tool may maintain contact with the components to be joined only with difficulty. Friction stir welding is also very time-consuming.

Laser welding is one of the fusion welding methods, the energy for melting a material being supplied via a laser beam. Due to the absorption of the laser power, an extremely rapid increase in temperature beyond the melting temperature of the components occurs at a joint on a surface of the components to be joined, so that a melt forms. To protect the weld against oxidation, the weld may be flushed with argon. It has been recognized that, by laser-welding an Al die-cast component to a further component, for example a further Al die-cast component, a leakage may occur due to the pores in the at least one Al die-cast component and/or due to the pores in the weld. Fluids may thus disadvantageously penetrate the casting wall or the wall of a housing, even directly, and/or fluids may flow over a leaky weld and a leaky interface of the two components at the weld. For example, fluids may thus flow between an interior of the housing and the surroundings of the housing. The components accommodated in an interior of a housing, for example electrical and/or electronic components, are thus no longer protected by the housing and/or the function of the components may no longer be safely ensured.

Multi-part housings are furthermore known, the housing parts being fastened to each other with the aid of screws. The screws and the designs of the housing parts needed therefor disadvantageously and unnecessarily take away space for the components arranged in an interior of the housing.

There is also continuous interest in accommodating as many components as possible, for example electrical and/or electronic components, in the smallest possible amount of space in an interior of a housing, the part of the housing facing the surroundings of the housing also needing to take up the smallest possible amount of installation space, for example in a vehicle.

### SUMMARY OF THE INVENTION

It is therefore an object of the present invention to at least partially eliminate the disadvantages described above. In particular, the object of the present invention is to provide a particularly space-saving and/or cost-effective and/or mechanically stable housing. The object of the invention is furthermore, in particular, to provide a housing, the tightness of the housing, in particular the tightness of a joint, formed by at last one joining surface of a housing lower part edge of a housing lower part of the housing and a second joining surface of a housing upper part edge of a housing upper part of the housing, is particularly reliably ensured. The object of the invention is also, in particular, to integrally bond a housing upper part to a housing lower part particularly rapidly and, at the same time, in a mechanically stable manner, by means of a laser welding process, to form a housing.

The above object is achieved by a housing for a vehicle device as well as a method for manufacturing a housing of this type. Features and details which are described in connection with the housing according to the invention also apply, of course, in connection with the method according to the invention and vice versa in each case, so that reference always is or may be made interchangeably with respect to the disclosure of the individual aspects of the invention.

According to a first aspect, the present invention shows a housing for a vehicle device, the housing being designed to receive at least electronic components. The housing comprises at least one metallic housing lower part having a housing lower part edge, the housing lower part edge having a first joining surface, at least one metallic housing upper part having a housing upper part edge, the housing upper part edge having a second joining surface, the second joining surface, in particular, corresponding to the first joining surface of the housing lower part edge, at least in sections. In the housing, at least the housing upper part edge having the second joining surface is arranged on the housing lower part edge having the first joining surface so as to form a joint with each other, at least one seal of the housing being also arranged in the joint, at least in sections, for the purpose of sealing an interior of the housing against surroundings of the housing. In the housing, the housing upper part edge is integrally bonded to the housing lower part edge in the joint at at least one welding section of the housing by means of a beam welding process, at least for the mechanical stabilization of the housing.

The housing can be advantageously provided for a DC-DC converter, a high-voltage converter, or an on-board charger. The above object may therefore also be achieved by a DC-DC converter of this type, a high-voltage converter, or an on-board charger having a housing of this type. Moreover, the object is also achievable by a vehicle having a high-voltage converter of this type, a DC-DC converter of this type, or an on-board charger of this type.

The vehicle device may be, for example, a high-voltage converter or an on-board charger (OBC) for a vehicle, in particular, for a motor vehicle, preferably for a passenger car and/or a truck.

The housing may have recesses for plug connectors, in particular electrical plug connectors. The housing advantageously includes at least one metallic housing lower part and one metallic housing upper part, so that the metallic housing lower part has an electrically shielding effect, and the upper housing part has an electrically shielding effect. In particular, the housing furthermore includes only the housing lower part and the housing upper part for receiving at least the electronic components. The housing is thus provided with a particularly simple design. In particular, the electronic components are furthermore received in the interior of the housing formed by the housing lower part and the housing upper part.

The housing lower part edge can be understood to be, in particular, an edge region of the housing lower part, and the housing upper part edge can be understood to be, in particular, an edge region of the housing upper part, the edge region of the housing lower part and the edge region of the housing upper part being arranged next to each other to form the housing for receiving at least electronic components. Other components may also be received instead of and/or in addition to the electronic components. In particular, the housing lower part edge is furthermore provided with a plate-shaped or essentially plate-shaped design, at least in sections. The housing upper part edge may also be provided with a plate-shaped or essentially plate-shaped design, at least in sections.

The first joining surface of the housing lower part edge can be formed by a part of the shell surface of the housing lower part, in particular, the housing lower part edge. The first joining surface of the housing upper part edge is formed by a part of the shell surface of the housing upper part, in particular, the housing upper part edge.

The first joining surface of the housing lower part edge and the second joining surface of the housing upper part edge are situated opposite each other. In particular, the first joining surface and the second joining surface abut each other without a gap or essentially without a gap, at least in a first section of the joint, to form a gap-free or essentially gap-free joint section. The housing upper part edge is preferably integrally bonded to the housing lower part edge at the at least one welding section of the housing by means of a beam welding process in a gap-free or essentially gap-free joint section. The housing may thus be particularly stable. It is furthermore additionally conceivable that the first joining surface and the second joining surface are spaced a distance apart at least in a second section of the joint for the purpose of forming a joint section having a gap. The at least one seal of the housing for sealing the interior of the housing against surroundings of the housing is preferably arranged in the joint section having a gap. The second section of the joint for receiving the seal preferably follows the first section of the joint in a vertical section through the housing lower part edge and the housing upper part edge, starting from the surroundings of the housing in the direction of the interior of the housing along the joint.

The seal of the housing is, in particular, stable at temperatures up to 200° C., preferably up to 120° C. In particular, the seal of the housing also seals the housing against (ambient) air and/or against hydrogen-containing compounds. In other words, the seal of the housing may be impermeable to hydrogen atom-containing compounds, such as water and/or hydrogen, and/or impermeable to air.

In particular, the housing can have a single welding section. The housing preferably has multiple welding sections, the housing upper part edge being integrally bonded to the housing lower part edge in the joint, in each case at a welding section of the multiple welding sections of the housing, in each case by means of a beam welding process, at least for the mechanical stabilization of the housing. In particular, the multiple welding sections are arranged at a distance from each other along the housing, in particular along the housing lower part edge or along the housing upper part edge. The housing thus may be particularly mechanically stable. An electrical resistance between the housing upper part and the housing lower part may thus also be kept particularly low.

A housing according to the invention may be advantageously particularly space-spacing, since, for example, installation space for screws for the mechanical stabilization of the housing may be avoided. At the same time, a housing according to the invention may be particularly cost-effective and fast to manufacture, since beam welding, in particular laser welding, may take place particularly rapidly, the housing also being particularly mechanically stable. The position of the at least one welding section or the position of the multiple welding sections may also be particularly easily changed, so that it is possibly to particularly easily respond, for example, to a change or adaptation of the housing or to electromagnetic compatibility requirements. In addition, the tightness of the housing, in particular the tightness of a joint, formed by at least one first joining surface of a housing lower part edge of a housing lower part of the housing and a second joining surface of a housing upper part edge of a housing upper part of the housing, may be particularly reliably ensured by the additional seal arranged in the joint.

It is also conceivable that the housing upper part edge has the features and details which have been mentioned in relation to the housing lower part edge or will be mentioned below and vice versa.

It may be advantageous if, in a housing according to the invention, the seal of the housing arranged in the joint for sealing the interior of the housing against the surroundings of the housing is arranged at a distance, in particular spatially at a distance, from the welding section integrally bonded in the joint by means of the beam welding process, in particular, the welding section having at least a distance of 2 mm to 10 mm, preferably a distance of 5 mm to 7 mm, from the seal arranged in the joint. When laser-welding, for example, an aluminum die-cast housing or an aluminum alloy die-cast housing, temperatures arise in the range of 600° C. for the purpose of causing the aluminum or the aluminum alloy to melt. If a laser beam strikes the seal directly, the seal may be destroyed. However, a high temperature may also be present due to the heat transfer by to the seal by the housing itself. The seal of the housing is therefore arranged at a sufficient distance from the welding section integrally bonded in the joint by means of the beam welding process to prevent a seal, for example a seal designed for a maximum of 120° C., from being damaged due to the beam welding.

In a housing according to the invention, the at least one welding section may be advantageously situated on a housing outer lateral surface formed by an outer lateral surface of the housing lower part and by an outer lateral surface of the housing upper part. The integral bonding of the housing upper part edge to the housing lower part edge in the joint may thus particularly easily take place at the at least one welding section of the housing by means of the beam welding process, for example, since the laser beam of a laser device may be particularly easily directed onto the at least one welding section of the housing from the surroundings of the housing.

In a housing according to the invention, the housing upper part edge may be particularly advantageously integrally bonded to the housing lower part edge in the joint at the at least one welding section by means of the beam welding process on at least one first joint end of the joint. The integral bonding of the housing upper part edge to the housing lower part edge may thus take place particularly easily and rapidly, for example, since the laser beam of a laser device may cause the housing upper part edge to melt and the housing lower part edge to melt at the same time. In particular, an end of the joint facing the environment of the housing forms the first joint end.

In a housing according to the invention, the housing lower part edge may have a projection extending, at least in sections, along the housing lower part edge, starting from the housing lower part in the direction of the housing upper part, the housing lower part edge being integrally bonded to the housing upper part edge in the joint (section) formed by the projection of the housing lower part edge and the housing upper part edge, in particular, at a first joint end of the joint formed by the projection of the housing lower part edge and the housing upper part edge, by means of the beam welding process, in particular, the projection of the housing lower part edge at least partially covering the housing upper part edge. The integral bonding of the housing upper part edge to the housing lower part edge may take place in a particularly advantageous manner. The expression “along the housing lower part edge” may be understood as being along the circumference of the housing in the region of the housing lower part edge and the housing upper part edge. In particular, the wall thickness of the housing upper part edge is reduced along the housing lower part edge in the region of the projection in such a way that the housing wall thickness of the housing does not increase along the housing lower part edge, in particular, remains the same or remains essentially the same. As a result, the amount of installation space required by the housing does not increase or does not essentially increase due to the projection. In particular, the projection of the housing lower part edge is furthermore designed to form a single piece with the housing lower part edge. It should be additionally noted that, in particular, the joining surface of the projection of the housing lower part edge and the second joining surface of the housing upper part edge form the aforementioned joint (section). The housing lower part edge is preferably integrally bonded to the housing upper part edge at a first joint end of the joint formed by the joining surface of the projection of the housing lower part edge and the second joining surface of the housing upper part edge, in particular the joint section, by means of the beam welding process, in particular, the seal of the housing not being arranged in the joint formed by the joining surface of the projection of the housing lower part edge and the second joining surface of the housing upper part edge. The seal of the housing may thus be particularly advantageously arranged at a distance from the welding section integrally bonded at the first joint end by means of the beam welding process, and a damage of the seal may be avoided.

The housing upper part edge can have a continuation extending outwardly away from the housing, the projection of the housing lower part edge and the continuation of the housing upper part edge contacting each other at an end face of the projection of the housing lower part edge for the purpose of forming a first joint end, and, in particular, the housing lower part edge being integrally bonded to the housing upper part edge at this first joint end by means of the beam welding process. In particular, the continuation may furthermore also extend at an inclination in relation to the projection of the housing lower part edge. Due to the contacting on the end face of the projection, a melt depot may form, and the housing upper part edge may be particularly advantageously integrally bonded to the housing lower part edge on the first joint end. The contacting of the continuation of the housing upper part and the projection of the housing lower part can be understood, in particular, as a gap-free abutment or an essentially gap-free abutment of the continuation and the projection. The integral bonding may thus take place in a particularly reliable manner. In addition, the wall thickness of the housing upper part edge is preferably reduced along the housing upper part edge in the region of the continuation. The housing lower part edge may thus, on the one hand, be particularly advantageously integrally bonded to the housing upper part edge at the first joint end by means of the beam welding process and, on the other hand, the amount of installation space required by the housing does not increase or does not essentially increase. The housing upper part edge may furthermore have multiple continuations corresponding to the projections of the housing lower part edge.

A groove-shaped recess may be formed in the housing lower part edge, at least in sections, by a first leg of the housing lower part edge facing the interior of the housing and by a second leg of the housing lower part edge situated at a distance from the first leg and facing the surroundings of the housing, the housing upper part edge being arranged in the grove-shaped recess of the housing lower part edge. Due to the groove-shaped recess, the arrangement of the housing upper part edge next to the housing lower part edge may take place in a particularly easy and precise manner. The groove-shaped recess may also be understood as an indentation. In particular, the seal of the housing may also be arranged in the groove-shaped recess between the housing lower part edge and the housing upper part edge. An adhesive may be particularly easily and advantageously arranged in the groove-shaped recess, for example by means of a dispensing process, as the seal of the housing for the purpose of sealing the interior of the housing against the surroundings of the housing. However, it is also conceivable that, in a housing according to the invention, in addition or alternatively to the groove-shaped recess, at least in sections, the second joining surface of the housing upper part edge is designed to be complete flat or essentially completely flat, at least in sections, and the first joining surface of the housing lower part edge is designed to be complete flat or essentially completely flat, the flat second joining surface and the flat first joining surface being arranged next to each other to form a flat joint, at least in sections, and the at least one seal of the housing being designed as a flat seal in this joint, at least in sections.

A housing according to the invention may particularly advantageously include a metallic connecting piece, in particular a plate-shaped metallic connecting piece, the metallic connecting piece being arranged with a third joining surface on an outer lateral surface of the housing lower part edge and on an outer lateral surface of the housing upper part edge, the housing lower part edge having the first joining surface, the housing upper part edge having the second joining surface, and the metallic connecting piece having the third joining surface forming the joint, and the housing lower part edge being integrally bonded to the metallic connecting piece in the joint at the welding section of the housing by means of a beam welding process, and the housing upper part edge being integrally bonded to the metallic connecting piece in the joint at a further welding section of the housing by means of a beam welding process. The geometry of the housing lower part edge and/or the geometry of the housing upper part edge may thus be kept particularly simple, since, for example, projections formed with the housing lower part edge may be avoided. At the same time, a housing may be manufactured particularly cost-effectively and rapidly, since beam welding, in particular laser welding, may take place particularly rapidly, the housing also being particularly mechanically stable. In particular, the wall thickness of the housing lower part edge or the wall thickness of the housing upper part edge is reduced along the housing lower part edge and/or along the housing upper part edge in the region of the metallic connecting piece in such a way that the housing wall thickness of the housing does not increase along the housing lower part edge or the housing upper part edge, in particular, remains the same or remains essentially the same. The metallic connecting piece, which has also been described, in particular, in the preceding section, can have a lower tenacity than the metallic housing lower part, and/or the metallic connecting piece may have a lower tenacity than the metallic housing upper part. The metallic connecting piece may thus abut the outer lateral surface of the housing lower part edge with the third joining surface of the metallic connecting piece gap-free or essentially gap-free, and/or the metallic connecting piece may abut the outer lateral surface of the housing upper part edge with the third joining surface of the metallic connecting piece gap-free or essentially gap-free. The housing lower part edge may thus be particularly advantageously integrally bonded to the metallic connecting piece in the joint at the welding section of the housing by means of the beam welding process, or the housing upper part edge may be particularly advantageously integrally bonded to the metallic connecting piece in the joint at the further welding section of the housing by means of the beam welding process.

It may be advantageous if, in a housing according to the invention, the housing upper part edge can be integrally bonded in a single point to the housing lower part edge at the at least one welding section by means of the beam welding process. The integral bonding at the at least one welding section by means of the beam welding process may thus take place particularly rapidly and easily. The single-point integral bonding may take place, for example, in that a laser beam of a laser beam device simultaneously melts the housing upper part edge and the housing lower part edge at a single point in the joint at the at least one welding section of the housing, the laser beam maintaining or essentially maintaining its position at the welding section. After the single-point melting of the housing upper part edge and the housing lower part edge, the laser beam is switched off and the melt solidifies, so that the housing lower part edge and the housing upper part edge are integrally bonded to each other.

In the housing according to the invention, at least the housing lower part may advantageously be a die-cast component, in particular an aluminum die-cast component, and/or the housing upper part may be a die-cast component, in particular an aluminum die-cast component. The housing may thus had complex structures and be provided with a particularly functional design, for example having receptacles for plug connectors and/or receptacles for printed circuit boards, and/or projections formed on the housing lower part edge, and/or continuations formed on the housing upper part edge, and/or different wall thicknesses of the housing lower part, and/or different wall thicknesses of the housing upper part. The aluminum die-cast component is made, in particular, from aluminum or an aluminum alloy. However, it is also conceivable that the housing lower part is a metal sheet, and/or the housing upper part is a metal sheet. It is furthermore also conceivable that the housing lower part is a die-cast component, in particular an aluminum die-cast component, and the housing upper part is a metal sheet, or vice versa. A housing lower part manufactured from a metal sheet or a housing upper part manufactured from a metal sheet may be particularly cost-effective.

The housing upper part edge may be particularly advantageously integrally bonded to the housing lower part edge by means of an adhesive arranged, at least in sections, in the joint formed by the first joining surface of the housing lower part edge and the second joining surface of the housing upper part edge as the seal of the housing. The adhesive is applied, in particular, in liquid form, in particular, the adhesive being cured afterwards. The application of a liquid adhesive may take place particularly easily and particularly rapidly, for example, by means of a dispensing process. The costs for manufacturing the housing may be kept particularly low thereby. The adhesive as the seal is used, on the one hand, to seal the interior of the housing against the surroundings of the housing and, on the other hand, the housing upper part edge is, in particular, integrally bonded to the housing lower part edge in the joint with the aid of the adhesive, and thus supports the mechanical stabilization of the housing which is integrally bonded by means of the beam welding process. It is alternatively conceivable that the seal is, in particular, an already cured seal, the cured seal being arranged in the joint.

In the housing according to the invention, the beam welding process may be a laser beam welding process. In the case of the laser welding process, it is advantageously possible to work in a particularly exact manner with a pinpointed, precise energy input. Complicated seam geometries may also be implemented. In addition, a laser welding takes place particularly rapidly, so that a housing may be welding particularly quickly.

It may be advantageous if, in a housing according to the invention, the housing has a housing wall thickness between 1 mm and 8 mm, in particular a housing wall thickness between 3 mm and 6 mm, at least at the at least one weld. The installation space of the housing at the at least one weld of the housing may advantageously be kept particularly small. In particular, no additional installation space is needed inside and/or outside for the mechanical stabilization of the housing. In particular, the housing wall thickness is derived from the wall thickness of the housing lower part and/or the wall thickness of the housing upper part.

According to a second aspect, the present invention shows a method for manufacturing a housing, the housing being designed, in particular, according to one of the preceding claims, the method including a provision of the housing lower part and a provision of the housing upper part as one step. The method further comprises an arrangement, at least in sections, of a seal on the first joining surface of the housing lower part edge of the provided housing lower part as a further step, and/or the method comprises an arrangement, at least in sections, of a seal on the second joining surface of the housing upper part edge of the provided housing upper part as one step. The method furthermore comprises an arrangement of the housing upper part edge with the second joining surface next to the housing lower part edge having the first joining surface for forming the joint as a further step, the seal arranged on the first joining surface and/or the seal arranged on the second joining surface being arranged in the joint, at least in sections, for the purpose of sealing an interior formed by the housing lower part and the housing upper part against surroundings of the housing lower part and the housing upper part. The method further comprises, as a further step, an integral bonding of the housing upper part edge to the housing lower part edge in the joint at the at least one welding section of the housing by means of the beam welding process, in particular a laser beam welding process, at least for the mechanical stabilization of the housing. The method steps described in this paragraph are preferably carried out in the specific sequence, in particular, the steps being carried out individually, together, singly, multiple times, and/or temporally in parallel, if technically sensible.

The method according to the second aspect of the invention therefore has the same advantages as already described in relation to the housing according to the first aspect of the invention.

The method steps described above and below may also be carried out individually, together, singly, multiple times, temporally in parallel, and/or consecutively in any sequence, if technically sensible.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a housing in a sectional view;

FIG. 2 shows a housing in a perspective sectional view;

FIG. 3 shows a housing in an external view;

FIG. 4 shows a housing, including a metallic connecting piece;

FIG. 5 shows a housing, including a metallic connecting piece in an external view; and

FIG. 6 shows a method.

### DETAILED DESCRIPTION

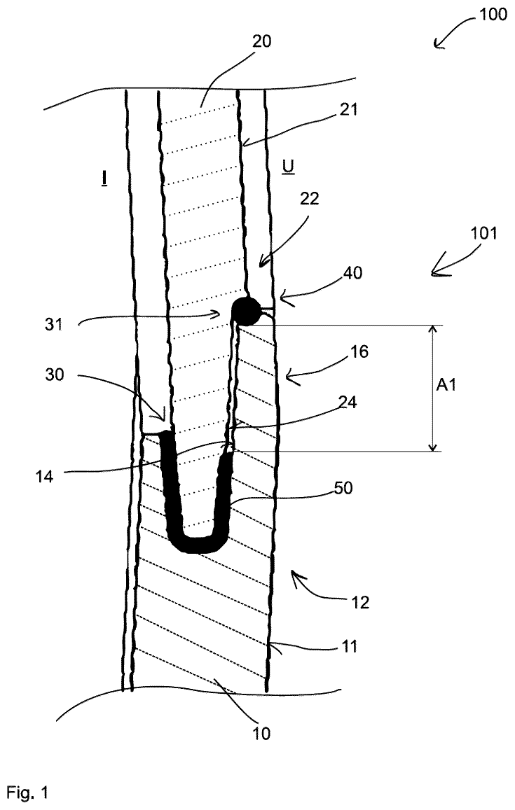

FIG. 1 shows a vertical sectional view of a part of a housing 100 for a vehicle device, housing 100 being configured to receive at least electronic components, in particular to receive at least electronic components at least in an interior I of housing 100. Housing 100 includes a metallic housing lower part 10 having a housing lower part edge 12, housing lower part edge 12 having a first joining surface 14. Housing 100 furthermore comprises at least one metallic housing upper part 20 having a housing upper part edge 22, in particular, housing upper part edge 22 having a second joining surface 24 corresponding, at least in sections, to first joining surface 14 of housing lower part edge 12. In particular, housing lower part 10 is a die-cast component, preferably an aluminum die-cast component, and/or housing upper part 20 is, in particular, a die-cast component, preferably an aluminum die-cast component. Housing upper part edge 22 having second joining surface 24 is furthermore arranged on housing lower part edge 12 having first joining surface 14 for the purpose of forming a joint 30 with each other. At least one seal 50 of housing 100 is also arranged in joint 30, at least in sections, for the purpose of sealing an interior I of housing 100 against surroundings U of housing 100. In addition, housing upper part edge 22 is integrally bonded to housing lower part edge 12 at at least one welding section 40 of housing 100 in joint 30, by means of a beam welding process, in particular by means of a laser beam welding process, at least for the mechanical stabilization of housing 100.

In addition, FIG. 1 furthermore shows that seal 50 of housing 100 arranged in joint 30 for sealing interior I of housing 100 against surroundings U of housing 100 is spatially arranged at a distance from welding section 40 integrally bonded in joint 30 by means of the beam welding process. In particular, welding section 40 has at least a distance A1 of 2 mm to 10 mm, preferably a distance A1 of 5 mm to 7 mm from seal 50 arranged in joint 30, in particular from an end of seal 50 following welding section 40 in joint 30. Distance A1 may depend on the temperature stability of seal 50. In addition, FIG. 1 also shows that the at least one welding section 40 is situated on a housing outer lateral surface 101 formed at least by an outer lateral surface 11 of housing lower part 10 and by an outer lateral surface 21 of housing upper part 20. In addition, FIG. 1 further shows that housing upper part edge 22 is integrally bonded to housing lower part edge 12 in joint 30 at the at least one welding section 40 by means of the beam welding process on at least one first joint end of 31 of joint 30. The end of joint 30 facing surroundings U of housing 100 forms first joint end 31. An end of joint 30 facing interior I of housing 100 may also form a further joint end, in particular a third joint end. FIG. 1 (cf. also FIG. 3; x direction), furthermore additionally shows that housing lower section edge 12 has a projection 16 extending along housing lower section edge 12, starting from housing lower part 10 in the direction of housing upper part 20, in particular, in the direction of housing upper part edge 22, projection 16 of housing lower part edge 12 at least partially covering housing upper part edge 22 and facing surroundings U, and housing lower part edge 12 being integrally bonded to housing upper part edge 22 in joint 30 formed by projection 16 of housing lower part edge 12 and housing upper part edge 22, in particular on a first joint end 31 of joint 30 formed by projection 16 of housing lower part edge 12 and housing upper part edge 22 by means of the beam welding process. It is also conceivable that housing lower part edge 12 has multiple projections of this type, for example 2 or 4 or 8 projections, along housing lower part edge 12, which are integrally bonded to the housing upper part, for example by means of the beam welding process in each case. In FIG. 1, housing upper part edge 22 is furthermore additionally integrally bonded to housing lower part edge 12 in a single-point manner at welding section 40 by means of the beam welding process. Moreover, FIG. 1 also shows that housing upper part edge 22 is integrally bonded to housing lower part edge 12 by means of an adhesive arranged, at least in sections, in joint 30 formed, by first joining surface 14 of housing lower part edge 12 and second joining surface 24 of housing upper part edge 22 as seal 50 of housing 100. Moreover, housing 100 may have a wall thickness between 1 mm and 8 mm, in particular, a wall thickness between 3 mm and 5 mm, in the region of weld 40.

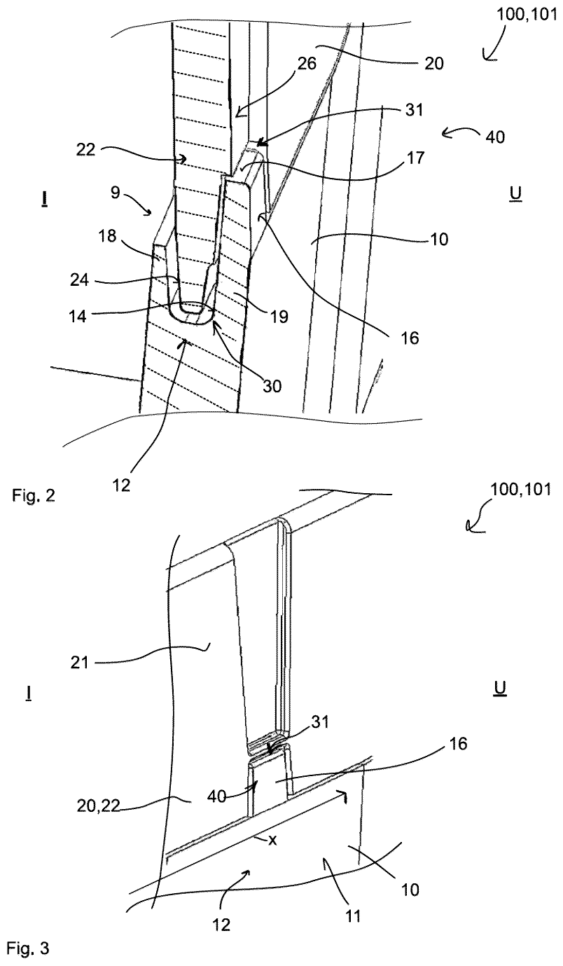

FIG. 2 shows a housing 100, as described in FIG. 1, seal 50 (cf., for example in FIG. 1) in joint 30 having been omitted for the sake of clarity, and housing upper part edge 22 still being integrally bonded to housing lower part edge 12 in joint 30 at at least one welding section 40 of housing 100 by means of a beam welding process for the mechanical stabilization of housing 100. In addition to FIG. 1, housing 100 in FIG. 2 has a groove-shaped recess 9, formed by a first leg 18 of housing lower part edge 12, which faces interior I of housing 100, and by a second leg 19 of housing lower part edge 12, which faces surroundings U of housing 100 and is situated at a distance from first leg 18, in housing lower part edge 12, at least in sections along housing lower part edge 12. Housing upper part edge 22 is furthermore arranged in groove-shaped recess 9 of housing lower part edge 12. First joining surface 14 and second joining surface 12 are situated at a distance from each other in a (second) section of joint 30 for the purpose of forming a joint section having a gap. The at least one seal 50 of housing 100 for sealing interior I of housing 100 against surroundings U of housing 100 may be arranged in the joint section having a gap in groove-shaped recess 9 (cf. FIG. 1). In particular, seal 50 has a thickness of approximately 0.8 mm at this point in housing 100. The thickness of seal 50 may vary, due to tolerances of housing lower part edge 12 and housing upper part edge 22. In addition, second leg 19 of housing lower part edge 12 has a projection 16 extending, at least in sections, along housing lower part edge 12, starting from housing lower part 10 in the direction of housing upper part 20, housing lower part edge 12 being able to be integrally bonded to housing upper part edge 22 in joint 30 formed by projection 16 of housing lower part edge 12 and housing upper part edge 22, in particular, at a first joint end 31 of joint 30 formed by projection 16 of housing lower part edge 12 and housing upper part edge 22, by means of a beam welding process. Furthermore, FIG. 2 also shows that housing upper part edge 22 has a continuation 26 extending outwardly away from housing 100. Projection 16 of housing lower part edge 12 and continuation 26 of housing upper part edge 22 contact each other on an end face 17 of projection 16 of housing lower part edge 12 for the purpose of forming a gap-free or essentially gap-free first joint end 31 in a (first) section of joint 30. Due to the contacting on end face 17 of projection 16, a melt depot may form, and housing upper part edge 22 may be particularly advantageously integrally bonded to housing lower part edge 12 on first joint end 31. Housing lower part edge 12 is integrally bonded to housing upper part edge 22 on this first joint end 31 by means of the beam welding process. In particular, housing upper part edge 22, in particular joining surface 24 of housing upper part edge 22, may be provided with a stepped design in a vertical section through housing 100, at least on side 100 facing surroundings U. First joining surface 14 of housing lower part 12 and second joining surface 24 of housing upper part 22 form a gap-free or essentially gap-free joint section for the integrally bonded arrangement of housing upper part edge 22 on housing lower part edge 12 in at least one first section of joint 30, and first joining surface 14 of housing lower part 12 and second joining surface 24 of the housing upper part forming a gap in at least one second section of joint 30 for the purpose of arranging seal 50. A mechanically stable housing may thus be created, and it may furthermore be ensured that an adhesive as seal 50 of housing 100 in sections may create a particularly advantageous integral bond between first joining surface 14 and second joining surface 24, and/or that interior I of housing 100 is particularly advantageously sealed against surroundings U of housing 100.

FIG. 3 shows an external view of a part of a housing 100, in particular as described, for example, in relation to FIG. 1 or FIG. 2. Housing 100 illustrated in FIG. 3 includes a metallic housing lower part 10 having a housing lower part edge 12 as well as an outer lateral surface 11 and a metallic housing upper part 20 arranged on housing lower part 10, which has a housing upper part edge 22 as well as an outer lateral surface 21. Housing lower part edge 12 has a projection 16 extending, at least in sections, along housing lower part edge 12 (cf. x direction), starting from housing lower part edge 12 in the direction of housing upper part 20, projection 16 of housing part lower edge 12 at least partially covering housing upper part edge 22 (not visible; cf. FIG. 2), housing lower part edge 12 being able to be integrally bonded to housing upper part edge 22 in joint 30 formed by projection 16 of housing lower part edge 12 and housing upper part edge 22, in particular, on a first joint end 31 of joint 30 formed by projection 16 of housing lower part edge 12 and housing upper part edge 22 by means of the beam welding process (for the sake of clarity, an integral bonding of housing lower part edge 12 to housing upper part edge 22 by means of a beam welding process has not yet taken place here). The housing may also include multiple projections 16 extending along housing lower part edge 12, which are designed in this way and situated a distance apart, starting from housing lower part 10 in the direction of housing upper part 20, in particular in the direction of housing upper part edge 22. The expression “along housing lower part edge 12” may be understood as being along the circumference of housing 100 in the region of housing lower part edge 12 and housing upper part edge 22. These projections 16 may be integrally bonded to housing upper part edge 22 by means of the beam welding process in each case.

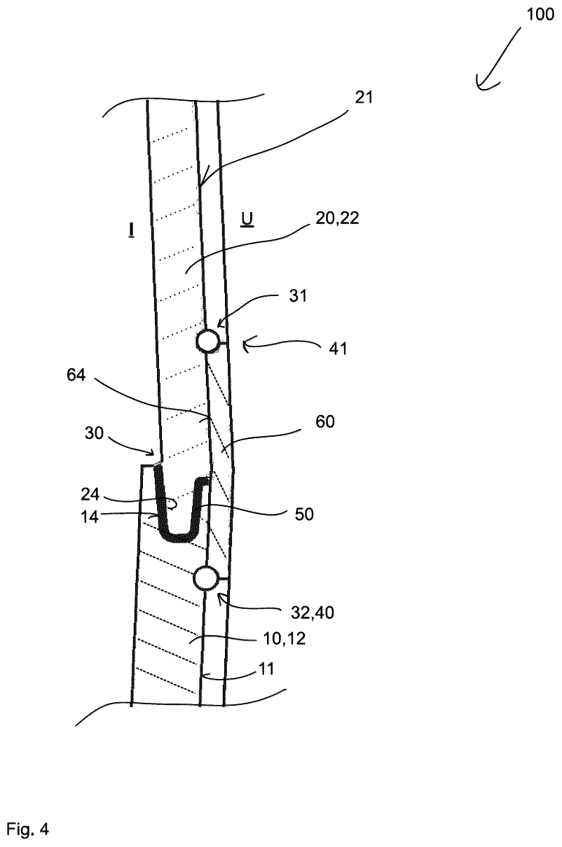

FIG. 4 shows a vertical sectional view of a part of a housing 100, in particular as described in relation to FIG. 1. Housing 100 has a metallic connecting piece 60, in particular, a plate-shaped metallic connecting piece 60, metallic connecting piece 60 being arranged with a third joining surface 64 on an outer lateral surface 11 of housing lower part edge 12 and on an outer lateral surface 21 of housing upper part edge 22, in particular, arranged in a gap-free manner or essentially in a gap-free manner. Housing lower part edge 12 having first joining surface 14, housing upper part edge 22 having second joining surface 24, and metallic connecting piece 60 having third joining surface 64 form joint 30. Housing lower part edge 12 is furthermore integrally bonded to metallic connecting piece 60 in joint 30 at welding section 40 of housing 100 on a first connecting piece end 61 of metallic connecting piece 60 by means of a beam welding process. Housing upper part edge 22 is furthermore integrally bonded to metallic connecting piece 60 in joint 30 at welding section 41 of housing 100 on a second connecting piece end 62 of metallic connecting piece 60 by means of a beam welding process. In addition, metallic connecting piece 60 may also have a lower tenacity than metallic housing lower part 10, and/or metallic connecting piece 60 may have a lower tenacity than metallic housing upper part 20. Metallic connecting piece 60 may thus be particularly advantageously arranged, in particular pressed, on outer lateral surface 11 of housing lower part edge 12 and/or particularly advantageously on outer lateral surface 21 of housing upper part edge 22 for the integral bonding by means of the beam welding process, for the purpose of obtaining a gap-free or essentially gap-free joint (section) 30.

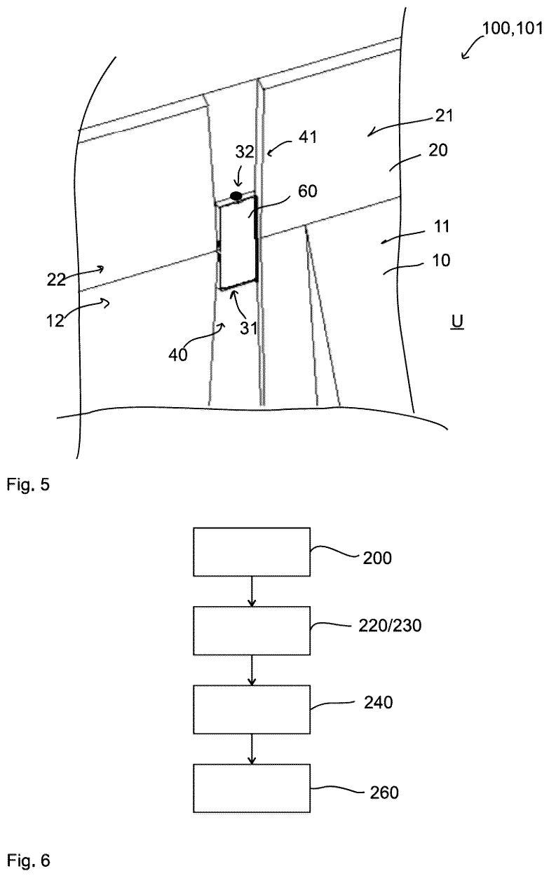

FIG. 5 shows housing 100 described in relation to FIG. 4, including metallic connecting piece 60, in an external view. Housing upper part 20 having housing upper part edge 22 and housing lower part 10 having housing lower part edge 12 are each designed to be thinner (smaller wall thickness) compared to the surrounding portion of housing upper part 20 or to the surrounding portion of housing lower part 10, in which metallic connecting piece 60 is arranged. This makes it possible to prevent connecting piece 60 from requiring additional installation space. It is conceivable that housing lower part 10, in particular housing lower part edge 12, has a continuation extended outwardly away from housing 100, and/or housing upper part 20, in particular housing upper part edge 22, has a continuation extending outwardly away from housing 100. The continuation of housing lower part edge 12 preferably contacts a first end face of metallic connecting piece 60 on first joint end 31 for the purpose of forming a first melt depot, and/or continuation 26 of housing upper part edge 22 preferably contacts a second end face of metallic connecting piece 60 on a second joint end 32 for the purpose of forming a second melt depot.

FIG. 6 discloses a method for manufacturing a housing 100. As a first step, the method includes a provision 200 of housing lower part 10 as well as a provision of housing upper part 20. As a further, subsequent step, the method comprises an arrangement 220, at least in sections, of a seal 50 on first joining surface 14 of housing lower part edge 12 of provided housing lower part 10, and/or an arrangement 230, at least in sections, of a seal 50 on second joining surface 24 of housing upper part edge 22 of provided housing upper part 20. As a further, subsequent step, the method comprises am arrangement 240 of housing upper part edge 22 having second joining surface 24 next to housing lower part edge 12 having first joining surface 14 for forming joint 30, seal 50 arranged on first joining surface 14 and/or seal 50 arranged on second joining surface 24 being arranged in joint 30, at least in sections, for the purpose of sealing an interior I formed by housing lower part 10 and housing upper part 20 against surroundings U of housing lower part 10 and housing upper part 20. As a further, subsequent step, the method comprises an integral bonding 260 of housing upper part edge 22 to housing lower part edge 12 in joint 30 at the at least one welding section 40 of housing 100, in particular at a melt depot of housing 100, by means of the beam welding process, preferably by means of a laser beam welding process, at least for the mechanical stabilization of the housing.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A housing for a vehicle device, the housing being configured to receive at least one electronic component, the housing comprising:
at least one metallic housing lower part having a housing lower part edge, the housing lower part edge having a first joining surface;
at least one metallic housing upper part having a housing upper part edge, the housing upper part edge having a second joining surface, at least the housing upper part edge having the second joining surface being arranged on the housing lower part edge having the first joining surface to form a joint with each other; and
at least one seal of the housing being arranged in the joint, at least in sections, to seal an interior of the housing from an exterior of the housing,
wherein the housing upper part edge is integrally bonded to the housing lower part edge in the joint at at least one welding section of the housing via a beam welding process, at least for a mechanical stabilization of the housing.

2. The housing according to claim 1, wherein the seal of the housing arranged in the joint for sealing the interior of the housing from the exterior of the housing is arranged at a distance from the welding section integrally bonded in the joint via the beam welding process, or wherein the welding section has at least a distance of 2 mm to 10 mm, or a distance of 5 mm to 7 mm, from the seal arranged in the joint.

3. The housing according to claim 1, wherein the at least one welding section is arranged on a housing outer lateral surface formed at least by an outer lateral surface of the housing lower part and by an outer lateral surface of the housing upper part.

4. The housing according to claim 1, wherein the housing upper part edge is integrally bonded to the housing lower part edge in the joint at the at least one welding section via the beam welding process on at least one first joint end of the joint.

5. The housing according to claim 1, wherein the housing lower section edge has a projection extending, at least in sections, along the housing lower section edge, starting from the housing lower part in a direction of the housing upper part, or wherein the projection of the housing lower part edge at least partially covers the housing upper part edge, the housing lower part edge being integrally bonded to the housing upper part edge in the joint formed by the projection of the housing lower part edge and the housing upper part edge or on a first joint end of the joint formed by the projection of the housing lower part edge and the housing upper part edge via the beam welding process.

6. The housing according to claim 5, wherein the housing upper part edge has a continuation extending outwardly away from the housing at an inclination in relation to the projection of the housing lower part edge, wherein the projection of the housing lower part edge and the continuation of the housing upper part edge contacts each other on an end face of the projection of the housing lower part edge to form a first joint end, and wherein the housing lower part edge is integrally bonded to the housing upper part edge on the first joint end via the beam welding process.

7. The housing according to claim 1, wherein a groove-shaped recess is formed in the housing lower part edge, at least in sections, by a first leg of the housing lower part edge facing the interior of the housing and by a second leg of the housing lower part edge facing the surroundings of the housing at a distance from the first leg, the housing upper part edge being arranged in the groove-shaped recess of the housing lower part edge, and the seal of the housing being arranged in the groove-shaped recess between the housing lower part edge and the housing upper part edge.

8. The housing according to claim 1, wherein the housing comprises a metallic connecting piece or a plate-shaped metallic connecting piece, wherein the metallic connecting piece is arranged with a third joining surface on an outer lateral surface of the housing lower part edge and on an outer lateral surface of the housing upper part edge, the housing lower part edge having the first joining surface, the housing upper part edge having the second joining surface, and the metallic connecting piece having the third joining surface forming the joint, and the housing lower part edge being integrally bonded to the metallic connecting piece in the joint at the welding section of the housing via a beam welding process, and wherein the housing upper part edge is integrally bonded to the metallic connecting piece in the joint at a further welding section of the housing via the beam welding process.

9. The housing according to claim 8, wherein the metallic connecting piece has a lower tenacity than the metallic housing lower part, and/or wherein the metallic connecting piece has a lower tenacity than metallic housing upper part.

10. The housing according to claim 1, wherein the housing upper part edge is integrally bonded to the housing lower part edge in a single-point manner at the welding section via the beam welding process.

11. The housing according to claim 1, wherein at least the housing lower part is a die-cast component or an aluminum die-cast component, and/or wherein the housing upper part is a die-cast component or an aluminum die-cast component.

12. The housing according to claim 1, wherein the housing upper part edge is integrally bonded to the housing lower part edge via an adhesive arranged in the joint formed, at least in sections, by the first joining surface of the housing lower part edge and the second joining surface of the housing upper part edge as the seal of the housing.

13. The housing according to claim 1, wherein the beam welding process is a laser beam welding process.

14. The housing according to claim 1, wherein the housing has a housing wall thickness between 1 mm and 8 mm, or a housing wall thickness between 3 mm and 6 mm, at least at the at least one weld.

15. A method for manufacturing a housing formed according to claim 1, the method comprising:
providing the housing lower part as well as providing the housing upper part;
arranging a seal, at least in sections, on the first joining surface of the housing lower part edge of the provided housing lower part or arranging a seal, at least in sections, on the second joining surface of the housing upper part edge of the provided housing upper part;
arranging the housing upper part edge having the second joining surface next to the housing lower part edge having first joining surface to form the joint, the seal being arranged on the first joining surface or the seal being arranged on the second joining surface being arranged in the joint, at least in sections, to seal an interior formed by the housing lower part and the housing upper part against surroundings of the housing lower part and the housing upper part; and
integrally bonding the housing upper part edge to the housing lower part edge in the joint at the at least one welding section of the housing via the beam welding process or a laser beam welding process, at least for the purpose of the mechanical stabilization of the housing.
